(19) United States
(12) Patent Application Publication
(10) Pub. No.: US 2026/0136086 A1
(43) Pub. Date: May 14, 2026

(54) ELECTRONIC DEVICE WITH UNDER-DISPLAY CAMERA

(71) Applicant: Asaf INBAR, Holon (IL)

(72) Inventor: Asaf INBAR, Holon (IL)

(21) Appl. No.: 19/119,863

(22) PCT Filed: Oct. 26, 2023
(86) PCT No.: PCT/IL2023/051108

§ 371 Date: Apr. 10, 2025

Related U.S. Application Data
(60) Provisional application No. 63/381,342, filed on Oct. 28, 2022.

(51) Int. Cl. H04N 23/57; H04N 23/55; H04N 23/81; H04N 23/90; H10K 59/121; H10K 59/65

(52) U.S. Cl. CPC H04N 23/57; H04N 23/55; H04N 23/81; H04N 23/90; H10K 59/121; H10K 59/65

(57) ABSTRACT

Some embodiments relate to an electronic device including a display screen unit including a display pixel matrix in a layer of a device panel exposed to an upper surface of the display screen unit; and at least one under-display camera system. The camera system can include an imaging lens unit including a lens exposed to at least a part of the upper surface of the display screen unit via inter-pixel gaps of spaces defined by the display pixel matrix; said lens being configured as a distributed lens having a surface configured in accordance with a continuous light wavefront curvature of a lensing effect to be applied to light incident on said distributed lens entering the imaging lens unit via at least said inter-pixel gaps. The spaced-apart lensing segments of the distributed lens can define respective spaced-apart surface portions of the continuous wavefront curvature aligned with said at least inter-pixel gaps.

### CROSS-REFERENCE TO RELATED APPLICATIONS

This application is a national phase filing under 35 C.F.R. § 371 of and claims priority to PCT Patent Application No. PCT/IL2023/051108, filed on Oct. 26, 2023, which claims the priority benefit under 35 U.S.C. § 119 of U.S. Provisional Patent Application No. 63/381,342, filed on Oct. 28, 2022, the contents of which are hereby incorporated in their entireties by reference.

### TECHNOLOGICAL FIELD

The present disclosure is in the field of electronic devices, and relates to a personal communication device, such as smartphone, smartwatch, or the like, utilizing an under-display camera.

### BACKGROUND

It is a common demand for a personal communication device, such as smartphone, to be a so-called “all-screen” device. Users require the largest-possible display on their phones while the phone is easy to hold. A periphery region around the screen is a free space that can be used for content. Hence, attempts are made to hide sensors and various other electronic parts behind the display.

It is also a common demand that a personal communication device has at least one built-in camera. Imaging optics of a camera is to be exposed to incoming light through an upper transparent panel of the device, and to properly image the collected light to the camera sensor. Therefore, the camera part typically occupies a portion of the upper panel outside that of the display part. This limits the active size of the display, and also limits a number of built-in cameras that can be used in the device. However, various modern applications, e.g., medical applications, require incorporations of multiple cameras in a personal communication device.

Techniques have been developed aimed at modifying personal communication devices to install a so-called “under-display camera”.

For example, patent publication CN 112863326 describes a transparent screen and a mobile terminal, where the transparent screen comprises, a substrate provided with a pixel array area comprising a first pixel array and a micro lens array arranged between pixel gaps of the first pixel array.

U.S. Pat. No. 10,163,984 describes a display having an array of pixels, where each pixel has a light-emitting diode such as an organic light-emitting diode, having an anode that is coupled to a thin-film transistor pixel circuit for controlling the anode. Transparent windows are formed in the display by replacing subpixels in some of the pixels with transparent windows. When subpixels are replaced by transparent windows, adjacent subpixels may be overdriven to compensate for lost light from the replaced subpixels. Adjacent subpixels may also be enlarged to help compensate for lost light. An array of electrical components such as an array of light sensors may be aligned with the transparent windows and may be used to measure light passing through the transparent windows.

### GENERAL DESCRIPTION

There is a need in the art for a novel approach for personal device configuration utilizing one or more built-in under-display cameras, enabling to minimize changes/modification to the device ‘display structure (its pixel matrix) while providing high quality operation (imaging) by the under-display cameras.

The present disclosure provides a novel configuration of a camera system enabling its operation as an under-display camera. The camera system includes at least one imaging unit and at least one optical sensor unit, where the optical sensor unit is associated with one or more imaging units and/or the imaging unit is associated with one or more optical sensor units, while all the imaging unit(s) and the sensor unit(s) are located below/behind an upper surface of a display defined by the pixel matrix of the display.

The imaging unit of the camera system typically includes one or more lenses, and possibly other optical element(s), e.g. polarizer(s). According to the present disclosure, the imaging unit includes a so-called “distributed lens” having a front and/or rear surface whose configuration corresponds to a predetermined continuous light wavefront curvature of a desired lensing effect to be applied by said distributed lens to light incident thereon. The camera system is installed in an electronic device (personal communication device) under the pixel matrix layer of a display screen unit (which is typically located under a transparent upper surface of the device) such that said wavefront defining surface of the distributed lens, directly or indirectly (depending on whether the lens is concave or convex), faces the upper surface of the electronic device and is thus exposed to the incoming light entering the device via spaces defined by the pixel matrix of the display screen unit.

It should be understood that a display pixel may be formed by a number of spaced-apart subpixels configured for transmission of different wavelength components of light, typically, primary colors—red, green and blue colors. In other words, the display pixel presents an RGB subpixels arrangement. For the purposes of the present application, the term “display pixel” should thus be interpreted broadly covering also such subpixels' arrangement. Accordingly, spaces defined by the pixel matrix of the display unit (or display screen unit) include inter-pixel gaps (gaps between the display pixels) and possibly also inter-subpixel gaps (gaps between subpixels of the display pixel and subpixels of the adjacent display pixels). These spaces are optically transparent regions defined/provided by the configuration of the pixel matrix of the display unit.

In the description below, the expressions “spaces defined by the pixel matrix” and “pixel matrix spaces” are used interchangeably. The meaning of the term “spaces” should be properly interpreted as described above.

It should be noted that the pixels and/or subpixels arrangement is configured as a pattern. Such pattern may be of certain fixed pattern parameters (i.e., shape, size and spatial frequency of the inter-pixel gaps and/or inter-subpixel gaps) or may be configured with one or more variable pattern parameter(s), or configured with random or quasi-random (almost random) configuration with respect to one or more such parameters of the pattern. The random or quasi-random configuration reduces the problem of vanishing light frequencies due to destructive interference from light waves going through the gaps.

The optical sensor unit of the camera system is located in a layer (or layers) downstream the imaging unit(s) (with respect to general direction of propagation of input light) and defines an imaging plane. The optical sensor unit receives light collected by said distributed lens and passed through the imaging unit and is configured to properly image the received light onto the imaging plane defined by the sensor unit.

More specifically, the wavefront curvature surface of the distributed lens extends along a region/zone of at least part of the pixel matrix of the display screen unit such that segments of the distributed lens, defined by segments of the wavefront curvature, are aligned with the pixel matrix spaces (inter-pixel gaps and inter-subpixel gaps) of said at least part of the pixel matrix layer of the display unit. Hence, said segments of the distributed lens are directly exposed to the upper surface of the display screen unit via the pixel matrix spaces.

It should be noted that for the purposes of the present application the term alignment or aligned, used in relation to relative accommodation between the segments of the distributed lens and the pixel matrix spaces of said at least part of the pixel matrix of the display, actually signifies that said segments of the distributed lens are either at least partially located within the inter-pixel gaps and within the inter-subpixel gaps or entirely located below/underneath the inter-pixel gaps and the inter-subpixel gaps. Such segments of the distributed lens are exposed to incoming light and thus function as active segments.

It should thus be noted that the term “under-display camera” does not exactly describe the physical structure of the device. Indeed, the camera system may or may not be entirely under the display unit (under the pixel matrix layer) because the distributed lens, being the uppermost element of the camera system may or may not be entirely under the display unit layer(s). The term “under-display camera” refers to the device functionality in the meaning that the camera system, namely its distributed lens, is exposed to the upper panel of the device via the pixel matrix spaces of the display unit (inter-pixel gaps and inter-subpixel gaps).

In some embodiments, the distributed lens may be configured such that the lens segments are at least partially physically incorporated within the pixel matrix layer of the display unit. Accordingly, the distributed lens is a physically patterned/segmented structure, such that an envelope defined by the shapes and sizes of the lens segments forms/corresponds to the predetermined wavefront curvature.

In some other embodiments, the distributed lens is located entirely under the pixel matrix layer, and the waveform curvature surface of the distributed lens is a continuous surface, while it still functions as the distributed/segmented lens because its inactive regions/segments between the active segments are aligned with (and thus screened from input light by) the pixels (or, generally, by sub-pixels) of the pixel matrix of the display unit.

Thus, it should be understood that in all the embodiments, the distributed lens is “functionally” a patterned structure. This is because the distributed lens includes spaced-apart active segments spaced by inactive regions/segments of the waveform curvature. The active segments are the segments of the wavefront curvature of the lens aligned with pixel matrix spaces (the inter-pixel gaps and inter-subpixel gaps), while being at least partially located within or entirely located below the pixel matrix spaces of the display unit, and are thus directly exposed to incoming light signals, and the inactive regions/segments of the waveform curvature are aligned with (located below) the display pixels (including also sub-pixels) and are thus “hidden/screened” from the incoming light.

In the description below, the distributed lens configuration and accommodation with respect to the pixel matrix of the display unit is at times described using the terms “alignment” or “aligned”. However, these terms should be properly interpreted as described above.

It should be understood that the configuration and operation (optical scheme and imaging function) of the above-described distributed lens is essentially different from a microlens array. Indeed, the microlens array includes identical spaced-apart microlenses, where each microlens is characterized by a wavefront curvature of the lensing effect (focusing effect) and is thus configured and operable as an independent lens, and the multiple wavefront curvatures of the multiple lenses are the same for all the microlenses in the array. On the contrary, in the distributed lens of the present disclosure, all the wavefront segments and thus the shapes and sizes of the spaced-apart lensing segments are different from one another. Moreover, each of the individual portions/segments (active segments) of the distributed lens has no meaningful lensing effect, but only the complete continuous wavefront curvature, i.e., envelope formed by shapes of all the segments together (active and passive), corresponds to the lensing effect.

Thus, according to one broad aspect of the present disclosure, it provides an electronic device comprising:
a display screen unit comprising a display pixel matrix in a layer of a device panel exposed to an upper surface of the display screen unit; and
at least one under-display camera system comprising:
   an imaging lens unit comprising a lens exposed to at least a part of the upper surface of the display screen unit via at least inter-pixel gaps of spaces defined by the display pixel matrix in at least a part of said display pixel matrix, said lens being configured as a distributed lens having a surface configured in accordance with a continuous light wavefront curvature of a lensing effect to be applied to light incident on said distributed lens entering the imaging lens unit via at least said inter-pixel gaps, such that spaced-apart lensing segments of the distributed lens defining respective spaced-apart surface portions of the continuous wavefront curvature are aligned with said at least inter-pixel gaps in said at least part of said display pixel matrix and are therefore directly exposed to the upper surface of the display screen unit via said at least inter-pixel gaps, while surface portions of the continuous wavefront curvature between said spaced-apart segments are screened from the upper surface by regions of the display pixel matrix outside said spaces defined by the display pixel matrix.

The camera system further includes an optical sensor responsive to image fragments created by the imaging lens unit from light collected by the distributed lens to generate corresponding fragmented image data; and an image processor configured to receive and process said fragmented image data to reconstruct an image from the fragmented image data.

The spaces defined by the display pixel matrix may further comprise inter-subpixel gaps, said spaced-apart segments of the distributed lens define respective spaced-apart surface portions of the continuous wavefront curvature aligned with said inter-subpixel gaps.

The lensing segments of the distributed lens correspond, respectively, to the portions of the continuous wavefront curvature, and are thus different from one another in at least one of geometry and orientation.

The spaced-apart lensing segments aligned with the inter-pixel gaps and inter-subpixel gaps of the pixel matrix of the display unit actually form spaced-apart “active portions” of the continuous wavefront curvature.

In some embodiments, the distributed lens is entirely located below said layer of the device panel containing said pixel matrix.

In some examples, the surface of the distributed lens configured in accordance with the continuous wavefront curvature of the lensing effect may be a continuous surface. The distributed lens may be made of any one of the following material compositions: plastic, glass, polymer, polycarbonate, transparent conductor.

In some other examples, said surface of the distributed lens configured in accordance with the continuous wavefront curvature of the lensing effect is a patterned surface, said lensing segments being at least partially located in the spaces defined by the display pixel matrix of said at least part of the pixel matrix of the display layer.

For example, said lensing segments are at least partially located in the inter-pixel gaps and inter-subpixel gaps defined by the display pixel matrix in said at least part of the pixel matrix of the display layer.

For example, at least some of said lensing segments are entirely located in the spaces defined by the pixel matrix in said at least part of the pixel matrix of the display layer.

The lensing segments may be made of molding pillars made of material of refractive index greater than air and are configured with heights varying as a function of their position along the distributed lens.

The lensing segments may be made of any one of the following material compositions: polymer, polycarbonate, glass, transparent semiconductor.

The display pixel matrix may comprise spaced-apart pixels, each pixel element comprising an arrangement of subpixels. The arrangement of subpixels may comprise a respective arrangement of light emitting elements. The light emitting element may comprise a LED-based structure, e.g., of any one of the following configurations: Organic LED (OLED), Plastic OLED (POLED), Active-Matrix OLED (AMOLED), Transparent OLED (TOLED), MicroLED.

In some embodiments, the light emitting element is configured with a top portion having a three-dimensional shape configured to maximize a distance between two neighboring subpixels while keeping given operational parameters of the light emitting elements of the subpixels.

For example the above can be implemented by optimizing configuration of conductors in pixel/subpixel structure. The conductors associated with the light emitting elements may be configured with predetermined aspect ratio between length and width of the cross section of the conductor while keeping a given cross section area of the conductor, thereby providing increased distance between edges of two adjacent conductors of two adjacent light emitting elements, respectively, while maintaining electrical properties of the conductors (e.g., current density).

In some embodiments, the layer of the display pixel matrix comprises, on one side thereof, said matrix of the light emitting elements, and comprises, in an opposite side of said layer, a matrix of light absorbers, where the light absorbers are aligned with the light emitting elements, respectively, thereby reducing diffraction occurring around edges of the spaces in between the light emitting elements.

In some embodiments, the layer of the display pixel matrix comprises light directing elements associated with the light emitting elements, respectively, configured to increase amount of light, incident onto the display pixel matrix, passing through the spaces defined by the pixel matrix. For example, said light directing element may comprise a pair of prisms at opposites sides of the light emitting element; or may comprise a curved fiber placed over the light emitting element.

In some embodiments, each of at least some of the light emitting elements of the pixel matrix is associated with a movement mechanism configured to controllably shift the light emitting element between its operative position, in which a light emitting surface of the light emitting element extends along the display pixel matrix layer and is exposed to the input light, and its inoperative folded position forming a window for the input light to pass through to the distributed lens of the camera system.

In some embodiments, the shape of the light emitting element can be optimized. For example, the light emitting element can be configured as a volumetric structure having a substantially planar base and a dome-like top shape or top shape in the form of spaced-apart protrusions (wave-like shape). By this, for a given/required surface area of the light emitting element, the top surface area emitting light is increased and a surface area of the base is decreased, as compared to those required for a cubic-like structure, thus allowing larger spaces defined by the pixel matrix.

In some embodiments, the optical sensor unit and the distributed lens are spaced from one another by a medium of a material composition and a thickness selected to maintain image formation scheme of light collected by the lens segments of the distributed lens on a light sensitive structure of the optical sensor unit. Said material composition of the media may comprise one of the following: polymer, polycarbonate, glass, transparent semiconductor.

In some embodiments, the surface of the distributed lens configured in accordance with the continuous wavefront curvature of the lensing effect is a front surface of the distributed lens facing the upper surface of the display screen unit.

In some other embodiments, the surface of the distributed lens configured in accordance with the continuous wavefront curvature of the lensing effect is a rear surface of the imaging lens facing said sensor unit.

In some embodiments, the optical sensor unit comprises a sensor matrix, where sensors of said sensor matrix are aligned with the spaces defined by the pixel matrix.

In some embodiments, the optical sensor unit comprises a sensor matrix configured as a distributed cluster of sensor pixels, where each cluster is a sub-matrix of said sensor matrix and the clusters are aligned with the spaces defined by the pixel matrix of the display screen unit.

The image processor is configured and operable to process fragmented image data indicative of output of the optical sensor unit by applying to said data a model-based processing utilizing a machine learning model to generate image data in which diffraction and chromatic effects associated with light propagation through the distributed lens are compensated.

In some embodiments, the camera system comprises at least one additional imaging lens unit comprising at least one respective additional lens configured as the distributed lens having a surface configured in accordance with a continuous light wavefront curvature of a lensing effect to be applied to light incident thereon via at least the inter-pixel gaps in at least one additional part of said display pixel matrix, said optical sensor being responsive to image fragments created by said at least one additional imaging lens unit.

In some embodiments, the device comprises at least one additional camera system, at least two camera systems comprising the distributed lenses extending along, respectively, at least two spaced-apart regions corresponding to respective at least two parts of the pixel matrix of the display screen unit. The device may include a data processor configured and operable to communicate with the image processor of said at least two camera systems.

According to another broad aspect of the disclosure, it provides a camera system configured to be installed as a built-in module in an electronic device underneath a pixel matrix of a display screen unit of the electronic device, said camera module comprising:
an imaging lens unit comprising a lens having at least one of its front or rear surfaces configured in accordance a continuous wavefront curvature of a desired lensing effect, such that when the camera module is installed in the electronic device, said at least one surface of lens is exposed to input light entering the device via a transparent panel thereof and propagating through spaces defined by said pixel matrix of the device, said lens being thereby operable as a distributed lens formed by an array of spaced-apart active lensing segments aligned with the spaces defined by the pixel matrix of the display unit;
an optical sensor unit located underneath the imaging lens unit and being responsive to image fragments created by the imaging lens unit to generate fragmented image data corresponding to the lensing segments; and
an image processor configured and operable to process the fragmented image data and reconstruct a real image.

According to yet another broad aspect of the present disclosure, it provides an electronic device comprising:
a display screen unit comprising a display pixel matrix comprising a matrix of light emitting elements exposed to an upper surface of the display screen unit; and
at least one under-display camera system comprising: an imaging lens unit comprising at least one lens accommodated to collect input light passing through optically transparent spaces defined by the display pixel matrix; an optical sensor receiving light collected by the imaging unit and generating corresponding image data; and an image processor configured to receive and process said image data to reconstruct an image;
wherein the display screen unit is configured to optimize the input light propagation onto said lens of the under-display camera system via the optically transparent spaces between the light emitting elements of the display pixel matrix, said display screen unit being characterized by at least one of the following:
conductors associated with the light emitting elements are configured with predetermined aspect ratio of length and width of a cross section of the conductor while keeping a given cross section area of the conductor, thereby maintaining electrical properties of the conductors while providing an increased distance between edges of two adjacent conductors associated with two adjacent light emitting elements, respectively, thereby increasing the amount of the input light reaching said lens via said spaces between the light emitting elements;
the display screen unit comprises a layer carrying said matrix of the light emitting elements at one side thereof and a matrix of light absorbers at an opposite side thereof, where the light absorbers are aligned with the light emitting elements, respectively, thereby reducing diffraction occurring around edges of the spaces in between the light emitting elements;
the display screen unit comprises light directing elements associated with the light emitting elements, respectively, said light directing elements being configured to increase the amount of the input light reaching said lens via said spaces between the light emitting elements;
the light emitting element is configured with a top portion having a three-dimensional shape configured to maximize a distance between two neighboring light emitting elements while keeping given operational parameters of the light emitting elements, thereby increasing the amount of the input light reaching said lens via said spaces between the light emitting elements; and
each of at least some of the light emitting elements of the pixel matrix is associated with a movement mechanism configured to controllably shift the light emitting element between its operative position, in which a light emitting surface of the light emitting element extends along the display pixel matrix layer and is exposed to the input light, and its inoperative folded position forming a window for the input light to pass therethrough.

According to yet further broad aspect of the present disclosure, it provides a display screen unit for use in an electronic device, the display screen unit comprising a display pixel matrix comprising a matrix of light emitting elements and being configured to optimize propagation of input light through optically transparent spaces between the light emitting elements of the display pixel matrix to thereby enable integration of at least one under-display camera in the electronic device, said display screen unit being characterized by at least one of the following:
conductors associated with the light emitting elements are configured with predetermined aspect ratio between length and width of the cross section of the conductor while keeping a given cross section area of the conductor, thereby maintaining electrical properties of the conductors while providing an increased distance between edges of two adjacent conductors associated with two adjacent light emitting elements, respectively, thereby increasing the amount of the input light passing through said spaces between the light emitting elements;
the display screen unit comprises a layer carrying said matrix of the light emitting elements at one side thereof and a matrix of light absorbers at an opposite side thereof, where the light absorbers are aligned with the light emitting elements, respectively, thereby reducing diffraction occurring around edges of the spaces in between the light emitting elements;
the display screen unit comprises light directing elements associated with the light emitting elements, respectively, said light directing elements being configured to increase the amount of the input light passing through said spaces between the light emitting elements;
the light emitting element is configured with a top portion having a three-dimensional shape configured to maximize a distance between two neighboring light emitting elements while keeping given operational parameters of the light emitting elements, thereby increasing the amount of the input light reaching said lens via said spaces between the light emitting elements; and
each of at least some of the light emitting elements of the pixel matrix is associated with a movement mechanism configured to controllably shift the light emitting element between its operative position, in which a light emitting surface of the light emitting element extends along the display pixel matrix layer and is exposed to the input light, and its inoperative folded position forming a window for the input light to pass therethrough.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to better understand the subject matter that is disclosed herein and to exemplify how it may be carried out in practice, embodiments will now be described, by way of non-limiting examples only, with reference to the accompanying drawings, in which:

FIG. 1 is a schematic illustration of an electronic device of the present disclosure including an under-display built-in camera module, where two possible alternative configurations of a camera lens are shown;

FIG. 2A schematically illustrates a pair of neighboring display pixels each formed by a sub-array of subpixels;

FIGS. 2B and 2C exemplify a display pixel matrix (FIG. 2B) formed by the display pixels of FIG. 2A, and the resulting matrix of spaces formed by inter-pixel and inter-subpixel gaps (FIG. 2C);

FIG. 3 schematically exemplifies integration of multiple built-in under-display camera systems, or an under-display camera system formed by multiple imaging units, of the present disclosure in a personal electronic device such as a smart phone device;

FIGS. 4A to 4D illustrate four exemplary configurations, respectively, of a part of the electronic device of the present disclosure including a display unit and an under-display camera system, where the distributed lens is a patterned structure and can be either entirely located within the pixel arrangement of the display unit (FIG. 4A), or partially located within the pixel arrangement of the display unit (FIGS. 4B-4D), and where the sensor unit may be of different configurations;

FIGS. 5A and 5B illustrate two more examples of the electronic device of the present disclosure, where the distributed lens is a continuous nonpatterned structure being entirely located under the pixel arrangement of the display unit;

FIGS. 6A to 6D exemplify the configuration and operation of a sensor pixel matrix of the optical sensor unit;

FIGS. 7A-7C and 8A-8E illustrate the principles of the aspect of the present disclosure for optimizing the configuration of the display pixel matrix to optimize operation of the under-display camera system;

FIGS. 9A and 9B show two more examples of the optimized arrangement of light e mitting elements of the display pixel matrix according to the present disclosure;

FIG. 10 exemplify a pixel/subpixel structure equipped with a foldable mechanism for shifting the pixel/subpixel structure between it operative and inoperative position, suitable to be used in a display of an electronic device; and

FIG. 11 illustrates, by way of block diagrams, the principles of machine learning model-based technique used in the image reconstruction from image data obtained by the camera sensor via the distributed lens.

### DETAILED DESCRIPTION OF EMBODIMENTS

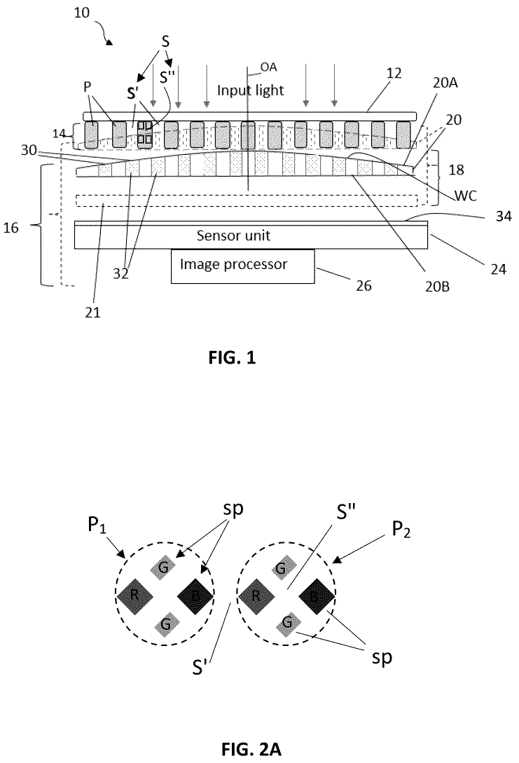

Reference is made to FIG. 1 schematically illustrating a part of a personal communication device 10 (electronic device having a display layer, e.g., touch display) showing the relative accommodation of some functional parts of the device 10 relevant for the description of the present disclosure. The device includes an optically transparent upper panel 12 (being single-or multi-layer structure), a display screen unit comprising a pixel matrix layer 14 below the transparent panel 12, and a built-in under-display camera system 16 configured according to the present disclosure.

It should be noted that the display unit may be of any known type, where the pixel matrix includes a matrix of light sensitive/emitting elements (referred to herein as LEDs), where LEDs may be of any known suitable type as well as any suitable geometry, and where the pixel may be of any known suitable arrangement (relative accommodation) of LEDs presenting sub-pixels (square, diamond, etc.). The sub-pixel arrangement forming the pixel may be that of primary colors, i.e., RGB arrangement, as well as more complex arrangement.

It should be understood that the arrangement shown in the figure may present a part of the display screen unit. The device may include more than one under-display camera system, i.e., camera systems located below the transparent panel 12 and extending along different regions aligned with the different sub-arrays of the pixel matrix of the display. In this schematic illustration, the camera system of the present disclosure is exemplified as including a single imaging unit associated with an optical sensor unit. It should, however, be noted that the principles of the present disclosure are not limited to such configuration. The under-display camera system of the present disclosure includes one or more imaging units in association with one or more optical sensor units. For example, the camera system may include multiple imaging units aligned with respective different sub-arrays of the pixel matrix of the display, and all imaging units are associated with the same optical sensor unit.

The under-display camera system 16 includes at least one imaging unit 18 (single such imaging unit being shown in the present example), at least one optical sensor unit 24 (single such optical sensor unit being shown in the present example), each associated with the at least one imaging unit, and also includes an image processor 26 (e.g., common for all optical sensor units if multiple such units are used).

It should be noted that the imaging unit 18 and the optical sensor unit 24 can be two separate physical entities, or one or more elements of the imaging unit (e.g., lens 20) can be chemically or electro-chemically deposited on a sensor of the optical sensor unit making them at least partially integral structure. Similarly, the image processor 26 can be a physical unit (ASIC chip) or the functionality of the image processor can be implemented/integral with a CPU and/or GPU of the electronic device 10.

The imaging unit 18 includes a light collecting lens 20 exposed to input light of the imaging unit and may optionally include one or more other lenses or other optical elements, which is/are schematically illustrated in the figure as a dashed-line box 21. As shown, the lens 20 is exposed to the upper transparent panel 12 of the device and is thus exposed to input light via spaces S (being holes or transparent regions which are inactive regions for the display unit operation) including spaces/gaps S′ between display pixels P of the pixel matrix 14 (inter-pixel gaps) and spaces/gaps S″ between subpixels SP (inter-subpixel gaps) of each of the display pixels P.

It should be understood that the subpixels' arrangement is shown in FIG. 1 schematically just in order to facilitate explanation, and the respective segments of the lens 20 aligned with the inter-subpixel gaps S″ is therefore not specifically shown in this figure.

As noted above, the pixel matrix and/or the subpixels arrangement is configured as a pattern of features of certain fixed parameters (i.e., shape, size and spatial frequency of the inter-pixel gaps and/or inter-subpixel gaps), or may be configured with random or quasi-random (almost random) configuration with respect to one or more such parameters of the pattern. The random or quasi-random configuration reduces the problem of vanishing light frequencies due to destructive interference from light waves going through the gaps.

Thus, in the present disclosure, a single pixel of the pixel matrix 14 refers to any possible arrangement of a number, configuration (geometry, spectral properties) and spatial relative accommodation (pattern) of subpixels, typically light emitting diodes (LEDs) or organic LEDs (OLEDs), in a predetermined scheme. As also indicated above, considering spectral properties of the subpixels, these may be RGB colors, RGB-Gold colors, RGB-Gold-Silver colors, etc.

In the examples of the present disclosure, for simplicity of illustration and explanation, the pixel matrix, as well as the subpixel arrangement, is exemplified as being configured as a pattern with repeating shape and spatial frequency of the gaps. However, it should be understood that the principles of the technique of the present disclosure are not limited to these specific examples, but also covers the display unit configurations with spatially varying or random pattern parameters, e.g., size and/or shape and/or spatial frequency of the gaps' accommodation.

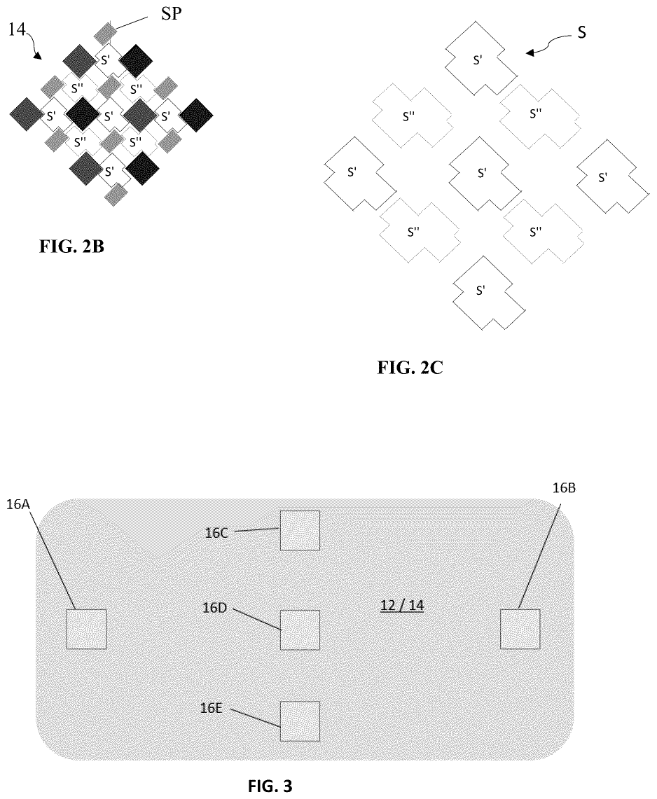

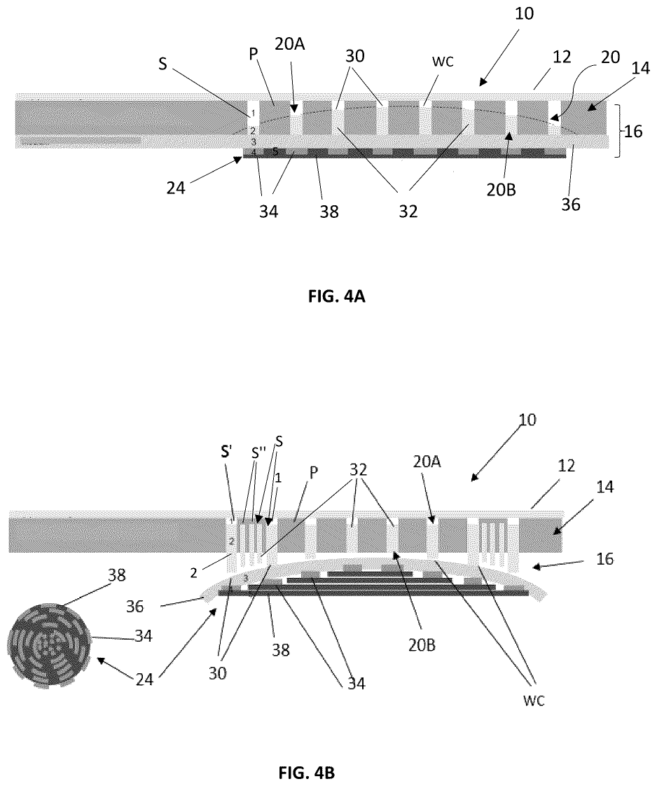

For example, FIG. 2A schematically illustrates a non-limiting example of two neighboring display pixels P₁ and P₂ of the display pixel matrix, where each display pixel includes four subpixels, generally designated SP, one red (R), two green (G), and one blue (B) subpixel. The display pixels P₁ and P₂ are distanced by inter-pixel gap S′ between them, and/or the subpixels SP within the pixel, as well as subpixels of neighboring pixels are distanced by inter-subpixel gaps S″. The gaps S′ and S″ define together the pixel matrix spaces S forming transparent regions for the incoming light. The input light reaching the camera system 16 passes through the inter-pixel gaps S′ and may pass through the inter-subpixel gaps S″ of the pixel matrix of the display unit.

FIG. 2B illustrates the display pixel matrix 14 formed by array of pixels distanced by the inter-pixel gaps S′, where each pixel is a sub-array of subpixels SP distanced between them by the inter-sub-pixel distance S″, which is also the distance/gap between the adjacent subpixels of the neighboring pixels. FIG. 2C illustrates the resulting arrangement (matrix) of spaces S defined by the display pixel matrix, thus forming a matrix of transparent areas being the areas of gaps S′ (inter-pixel gaps) and gaps S″ (inter-subpixel gaps).

Referring back to FIG. 1, it illustrates two possible alternative configurations of the lens 20: in one configuration, the lens 20 shown by solid lines is entirely located under the pixel matrix layer 14, and in the alternative configuration the lens 20 shown in dashed curves is at least partially accommodated within the spaces S defined by the pixel matrix 14. Various specific examples of these embodiments will be described more specifically further below.

In all the embodiments of the present disclosure, the lens 20 of the imaging unit 18 is configured as a distributed lens having at least one of its front or rear surfaces (front surface 20A in the present non limiting example of FIG. 1) configured in accordance with a predetermined continuous light wavefront curvature WC of a lensing effect (imaging effect) which is to be applied by the lens to incident light in order to create an image of the input light field on an imaging plane defined by the optical sensor unit 24 (its light sensitive surface). The wavefront defining surface 20A of the distributed lens 20 extends along a region corresponding to a region of at least part of the pixel matrix 14 of the display screen unit, such that portions/segments 30 of the surface 20A defining respective portions of the continuous wavefront curvature WC are aligned with the pixel matrix spaces S (i.e., inter-pixel gaps S′ and inter-subpixel gaps S″ of the pixel matrix. Hence, the surface portions 30 of the distributed lens 20 and corresponding lens segments 32 are directly exposed to the input light entering the device via the upper panel 12 and propagating through the spaces S formed by the pixel matrix 14 of the display unit.

It should be understood, although not specifically shown in FIG. 1, that the active segments 32 of the lens include spaced-apart segments aligned with the inter-pixel gaps S′ and the inter-sub-pixel gaps S″. The inter-subpixel gaps S″ and the inter-pixel gaps S′ may be of substantially the same size/area as will be described more specifically further below.

The optical sensor unit 24 may be of any suitable configuration defining a light sensitive surface/arrangement which is responsive to a light field created by the imaging unit 18 from the light collected by the distributed lens 20 to generate corresponding image data. The image processor 26 is configured to receive and process this image data to reconstruct an image of a scene being imaged by the camera system. The configuration and operation of the image processor 26 will be described further below. Also, described further below are various exemplary configurations of the optical sensor unit 18.

Thus, the distributed lens 20 of the imaging unit is configured in accordance with a continuous wavefront defined by a desired lensing effect to be provided by the entire lens and is configured as a functionally patterned structure with respect to its exposure to input light. The distributed lens 20 can physically be a continuous nonpatterned structure (in case it is entirely located under the pixel matrix layer 14 as exemplified by solid-curves lens 20 in FIG. 1) or can be a segmented/patterned structure (in case it is entirely or partially located within the spaces defined by the pixel matrix layer 14 as exemplified by dashed-curves lens 20 in FIG. 1). However, in all such configurations, the distributed lens 20 defines an array of functionally different segments, i.e., defines spaced-apart lensing segments 32 (active segments of the wavefront curvature WC) which are aligned with the pixel matrix spaces S of the display unit and which are spaced by inactive segments of the wavefront curvature WC. Such inactive segments of the wavefront curvature WC are segments aligned with the subpixels and may be defined by portions/segments of the continuous lens structure 20 (in case the lens 20 is entirely located under the pixel matrix layer 14) or may not be part of the physical lens structure (in case the lens 20 is at least partially located within the pixel arrangement 14).

Thus, the lensing segments 32 are active segments in the meaning that they are exposed to the upper panel 12, and thus to the input light, via the spaces S formed by the display pixel matrix 14 (including inter-pixel gaps S′ and inter-subpixel gaps S″). These lensing segments 32 correspond, respectively, to the portions of the continuous wavefront curvature WC, and are thus different from one another in geometry/shape and/or orientation with respect to the optical axis OA of the lens 20. The active lensing segments 32 of the distributed lens 20 are configured (shaped) to define an envelope of either one or both of the front and rear surfaces of the lens corresponding to the predetermined wavefront curvature WC (envelope) of the lensing effect. In other words, the active lensing segments 32, being segments aligned with the pixel matrix spaces S of the display unit, have gradually varying heights to form segments of a common wavefront of the lensing effect.

The distributed lens 20 may be made of any known suitable material, such as plastic, glass, polymer (e.g., Electro Active Polymer (EAP)), polycarbonate, transparent conductor or semiconductor such as Indium Tin Oxide (ITO), or, generally, any material with relevant transparency level and refractive index. The distributed lens 20 and the optical sensor unit 18 may be spaced between them by a medium of properly selected material composition (e.g., polymer (e.g., EAP), Polycarbonate, glass, or ITO) and thickness to maintain the desired imaging scheme of light propagation through the imaging unit 18 onto an imaging plane defined by the sensor unit 18.

Thus, the technique of the present disclosure provides the camera system 16 which utilizes at least one distributed lens 20 enabling the camera system configuration and operation as an under-display camera. Given a pixelated display, the interspaces/gaps S between the display pixels P, as well as gaps S″ between the subpixels SP) are treated to allow for the transmission of visible and possibly also near infrared light (transparent or free space propagation).

The above can for example be implemented by making the spaces S (“dead” spots) between the display pixels P and between the subpixels SP as perforations of dimensions allowing light in these spectra to be transmitted through these spaces without significant intensity loss. According to another example, the spaces S (“dead” areas) can be made from transparent material. This is especially appealing in OLED displays where areas with conducting lines or active components can be designed to be of minimal surface area and therefore increase the overall transmitted light. The optically transparent area can be maximized to pass more light through the display layers, by narrowing conductive traces and increasing their thickness to keep the same cross section area for the required electrical properties of the conductors (e.g., current density).

It should be noted that, in operation of the electronic device with the under-display camera, the “display unit” can be powered down during each “imaging session” performed by the camera system with the distributed lens, such that the display unit does not interfere with the light input around the region/area of the distributed lens. In this context, the “display unit” can be the entire display of the electronic device, or a portion (or portions) of the display that will power down during the imaging session. In this context, “imaging session” is a series of one or more photograph images or one or more video frames or one or more full cycles of operation of the image sensor or processor intended at producing a photograph or video frame.

As described above, the distributed lens 20 can be implemented inside or below the pixel matrix spaces S of the display unit (both options being presented by non-limiting examples in FIG. 1). Considering the distributed lens configuration at least partially inside the pixel matrix spaces S, the distributed lens implementation may imply molding pillars made of material of refractive index greater than air and of varying height as a function of their position across the surface of the lens such that the desired wavefront curvature envelope is formed. Such arrangement effectively acts as a lens as it induces a quadratic phase in the light propagating through the pixelated display. Considering the distributed lens (e.g., Fresnel lens) configuration entirely below the pixel matrix layer of the display unit, the distributed lens is configured as a continuous (nonpatterned) structure with front and/or rear surface of the desired wavefront curvature. In this implementation, the distributed lens may be mechanically supported on its periphery by either stiff standoffs or linear actuator to facilitate movement on the optical axis for autofocus and/or compensation for temperature and/or manufacturing tolerances.

The optical sensor unit 24 is located below the distributed lens 20 such that a light sensitive surface/structure 34 (sensor array) of the optical sensor unit 24 faces the rear surface 20B of the lens 20 and is spaced from this surface 20B by a gap of a suitable medium (e.g., air gap). The size/thickness of this gap is selected to obey the image formation condition.

It should be noted that the camera system 16 is preferably configured with an optical zoom mechanism, i.e., movement of the lens 20 (or one or more portions or segments of the lens) and/or the optical sensor unit 24 to change the apparent closeness of the scene being imaged by increasing the focal length. Considering the distributed lens 20 configured as physically continuous nonpatterned structure entirely located under the display pixel matrix layer 14, the optical zoom mechanism can be implemented by movement of the distributed lens and/or the optical sensor unit. In case the distributed lens 20 is a segmented/patterned structure entirely or partially located within the pixel matrix 14 of the display unit, the optical zoom mechanism can be implemented by movement of the optical sensor unit 24 towards and away from the lens 20.

It should be noted that the typical sizes of the pixel matrix spaces of the display unit (micrometer size, e.g., 27.5 μm of the inter-pixel and inter-subpixel gap) results in diffraction effects which unavoidably degrade the image formed on the sensor array. This degradation affects the sharpness of the image being formed, as well as introduces chromatic aberrations, since the diffraction is wavelength dependent. To correct/compensate for these degradations, the image data generated by the optical sensor unit (which is in the form of image fragments/data pieces) is further processed by the image processor 26 to reconstruct a high-quality image of an object/scene being imaged by the camera system.

The image processor 26 may be configured and operable to utilize dedicated image processing algorithms and/or deep neural network(s) (NN(s)) that is/are properly modeled and trained to match a clear and sharp picture based on the original image. The NN operates to receive the raw image data and output sharp reconstruction of the real image. The distortion and physical effects are modeled in a differentiable manner to help the NN, by introducing synthetic data for training. Super resolution techniques can be applied as well. The training can be self-supervised, as the real images are synthetically corrupted and learning mode is performed to reconstruct them back. This will be described more specifically further below.

It should be understood that the camera system (its distribution lens) may be placed at/aligned with any region of the display unit (i.e., of the pixel matrix layer of the display unit). Also, the electronic device may include more than one such camera system associated/aligned with different regions/sub-arrays of the pixel matrix of the display unit, or more than one imaging units, where at least some of the imaging units or all of them are associated with a common optical sensor unit.

For example, the imaging unit may be aligned with the center region of the pixel matrix of the display unit, allowing video-conferencing with direct eye contact. Moreover, the freedom of placement of the imaging units (and thus of the camera system(s)) provided by the technique of the present disclosure allows using a pair of such cameras placed behind the display for stereoscopic imaging (3D scene capture by triangulation).

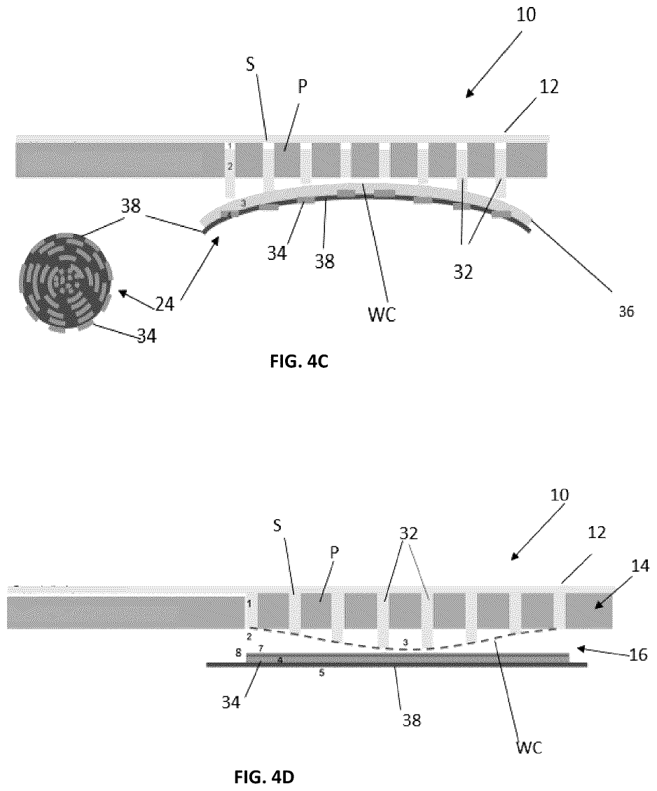

In this connection, reference is made to FIG. 3 exemplifying an electronic device 10, such as a smart phone device, having multiple built-in under-display imaging capabilities. This can be implemented by using multiple camera systems/modules—five such camera/stems/modules 16A, 16B, 16C, 16D, 16E being shown in this non-limiting examples. It should be understood that this can be achieved by using multiple camera modules, each including imaging unit and optical sensor unit; or can be implemented by using multiple camera system formed by multiple imaging units associated with one or more optical sensor units and one or more image processing units. These camera modules/systems are located entirely or partially under the display pixel matrix layer 14 (depending on the configuration of the distributed lens 20 as described above) and the imaging units are associated/aligned with different regions of the pixel matrix layer.

For example, for video conference, one of the “central” cameras 16C (central imaging systems), 16D, 16E may be selected (activated) in accordance with the orientation of user's line of sight (where the user is looking on the screen). For implementing 3D videos, two side cameras (side imaging systems) 16A-16B can be used.

It should be noted that two or more instances can be used for 3D vision and for video call eye-to-eye contact and orientation.

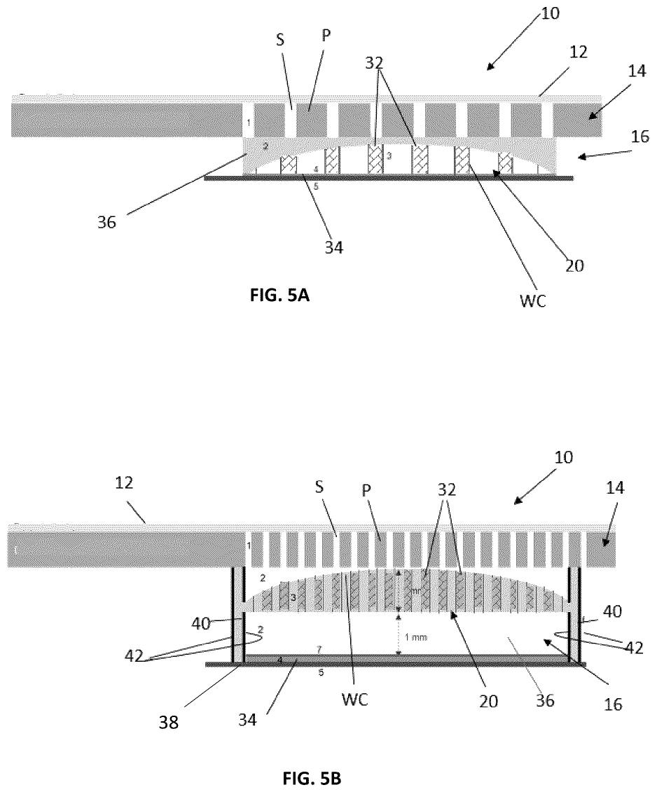

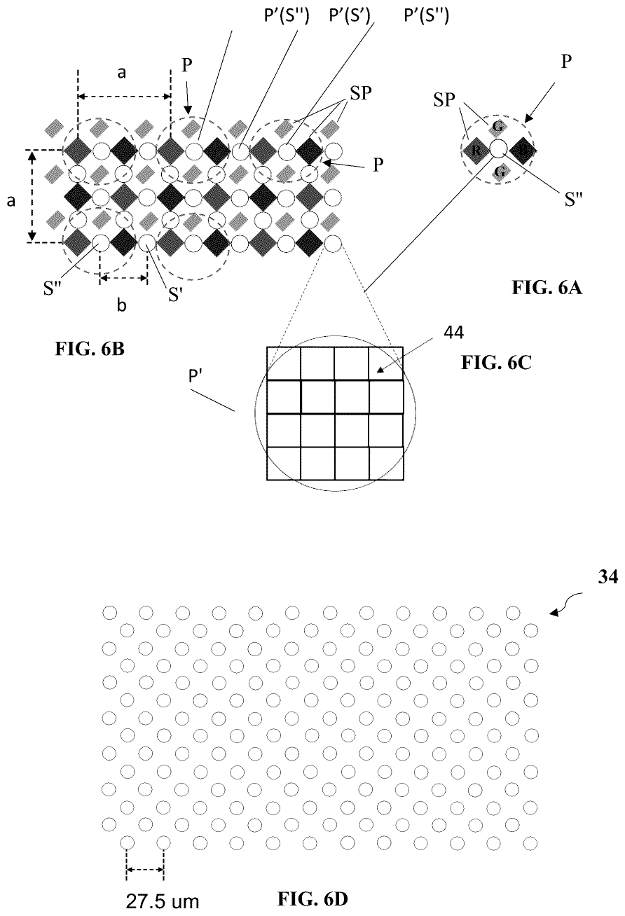

Reference is made to FIGS. 4A to 4D and FIGS. 5A-5B illustrating various specific not limiting examples of the configuration of the electronic device according to the present disclosure. In the figures, only that part of the electronic device is shown which is relevant to demonstrate the general principles and exemplary features of the technique of the present disclosure. To facilitate understanding and simplify illustrations, the same reference numbers are used to indicate common elements/features (i.e., functionally similar elements/features) in all the examples. In the figures, the layout of functional layers of the device is shown where the order of these layers from top to bottom is indicated by the layers'numbers.

In all these examples, the electronic device 10 is constructed generally similar to the above-described device of FIG. 1, namely includes a display screen unit (layer 1) including the pixel matrix layer 14 under the upper panel 12, and at least one built-in under-display camera system 16 including an imaging unit 18 which may be constituted only by the distributed lens 20 (layer 2), and an optical sensor unit 24. The latter is formed by a light sensitive surface/structure (layer 4) defining a sensor pixel matrix 34, and a substrate structure 38 (layer(s) 5) for placing the sensor and its readout circuit (electrical connectors). FIGS. 4B and 4C also show schematically top views of the optical sensor unit 24. The distributed lens 20 (or its active segments 32) may be made of any suitable material having relevant transparency level and refractive index, e.g., any one of the following: plastic, polymer, Polycarbonate, glass, transparent semiconductor (e.g., ITO).

It should be noted that, in order to simplify illustration, the inter-subpixel gaps S″ and corresponding active segments 32 of the distributed lens 20 are shown only in some of these examples (FIGS. 4B and 4C) and are shown schematically in relation to some of the pixels. However, it should be understood that the subpixel arrangement and associated inter-subpixel gaps are relevant for all the examples of the present disclosure.

The lens 20 and the light sensitive surface of the optical sensor unit 24 are distributed/split structures defining, respectively, active/lensing elements 32 of the wavefront profile/curvature WC and the corresponding sensor pixel matrix 34. Each sensor pixel of the matrix 34 is a colored pixel, typically RGB pixel and/or other colors.

It should be noted that the sensor pixel matrix 34 of the sensor unit 24 can be configured to define an array of sensor pixel clusters. The cluster includes the maximum number of sensor pixels that can fit between the display's pixels. The active/lensing segments 32 of the distributed lens 20 are vertically aligned with the sensor clusters. This will be described more specifically further below.

As also shown in the figures, a suitable medium 36 (layer 3) is provided between the imaging unit (e.g., between the rear surface of the distributed lens 20 by which it faces the sensor pixel matrix) and the light sensitive structure 34 of the optical sensor unit. Such medium 36 may include any material with relevant transparency level and refractive index, e.g., any one of the following: air, polymer (e.g. EAP), polycarbonate, glass, or transparent semiconductor (e.g., ITO).

FIGS. 4A to 4D show four examples, respectively, of the electronic device 10 of the present disclosure, in which the distributed lens 20 is a patterned/segmented structure whose active segments 32 are at least partially located within the spaces defined by the pixel matrix 14 of the display unit, i.e., distributed between the display pixels and subpixels.

In the example of FIG. 4A, the active segments 32 are entirely located in the spaces S defined by the display pixel matrix 14, i.e., within the inter-pixel gaps S and inter-subpixel gaps (not shown here). The wavefront curvature WC is formed by the envelope defined by surface portions/segments 30 of the upper/front surfaces of the lensing segments 32 forming an upper surface 20A of the distributed lens 20, while the rear surface 20B of the lens 20 is substantially planar.

Also, in this specific non-limiting example, the sensor pixel matrix 34 of the optical sensor unit is configured as a planar/flat structure (i.e., not distributed clusters). The optical sensor unit receives the light field indicative of an image created by the imaging unit (the distributed lens which collects light through the pixel matrix spaces of the display unit) and generates corresponding image data to be processed by the sensor image processor (not shown here).

The medium 36 between the rear surface 20B of the distributed lens 20B and the sensor pixel matrix 34 of the sensor unit may be an air gap (layer 3) of a predetermined size.

In the examples of FIGS. 4B-4D the active segments 32 are at least partially located in the pixel matrix spaces S (inter-pixel gaps S′ and inter-subpixel gaps S″ which are not specifically shown in FIG. 4D) and project therefrom towards the optical sensor unit 16 (its light sensitive structure 34). Also, in these non-limiting examples, the wavefront curvature WC providing the desired lensing effect is formed by the envelope defined by surface portions/segments 30 of the rear surfaces of the lensing segments 32 forming the rear surface 20B of the distributed lens 20, while the front surface 20A of the lens 20 is substantially planar. In these examples, the pixel matrix 34 of the sensor unit is a three-dimensional structure, i.e., multi-layer structure, or so-called “distributed clusters”.

Also, in the non-limiting examples of FIGS. 4B and 4C, the envelope formed by the rear surface portions 30 of the lensing segments 32 is illustrated as defining the concave wavefront curvature, while in the example of FIG. 4D, this is exemplified as convex wavefront curvature.

As also shown in the figures, in the example of FIGS. 4B and 4C, the sensor clusters layer (light sensitive layer 4) has or defines a curved shape corresponding to lens curvature. This enables to make substantially flat envelope of the front/top surface 20A of the distributed lens 20. In the example of FIG. 4B, this is implemented by configuring the sensor unit 24 with stacked substrate layers 38 for placing the clusters of sensing elements/pixels 34. In the example, of FIG. 4C, this is implemented by using in the optical sensor unit 24 a FLEX material or sphere-shaped material to form the substrate layer 38.

As exemplified in FIG. 4D (and might be relevant for any other example as well) the optical sensor unit 24 may also include a protective layer 8 located on top of the sensor matrix layer 4 and formed with an anti-reflective (AR) coating layer 7. Such AR coating is placed on the front/upper surface of the sensor to prevent reflections and formations of ghost images. Additional AR coatings may be added on the outer surface of the display unit structure facing the sensor unit.

FIGS. 5A and 5B show two examples, respectively, of the electronic device 10 in which the distributed lens 20 is located entirely under the pixel matrix layer 14 of the display unit and is thus a continuous nonpatterned structure. In both examples, the distributed lens 20 faces the display unit layer 14 by its continuous upper surface 20A configured as the desired wavefront curvature WC of the lensing effect and has a substantially flat rear surface 20B by which it faces the light sensitive structure 34 of the sensor unit 24.

The spaced-apart segments 32 of the distributed lens 20 that are aligned with (located below) the pixel matrix spaces S of the display unit (inter-pixel gaps and inter-subpixel gaps) are exposed to incoming light via said spaces and are thus “active segments”, i.e., correspond to/form functionally “active” portions of the wavefront curvature WC. These spaced-apart active segments 32 are spaced by non-active segments of said lens 20 aligned with (located below) the pixels P and being aligned with the subpixels of the display pixel matrix, and thus correspond to/form non-active portions of the wavefront curvature WC which do not receive incoming light because they are screened from the incoming light by the subpixels of the display pixel matrix layer 14.

The lens 20 may be made of glass, and the material medium 36 filling a gap between the surface 20A and the display pixel matrix 14 may for example include a plastic or PET (Polyethylene terephthalate) material. The pixel matrix spaces S may be implemented as perforations/holes, i.e., air spaces.

As exemplified with reference to FIG. 5B, the lens 20 may be made of glass and may be constructed by casting defining bounding glass pipes 40 which serve as support elements for supporting the lens 20 between the display layer 14 and the substrate 38 carrying the light sensitive surface/arrangement 34 of the optical sensor unit. The spaces between the pixels in the pixel matrix 14 of the display layer may be air or just transparent gaps. As also exemplified in the figure, the support pipes 40 may be formed, on their outer surfaces, with anti-reflective coatings 42.

Thus, the distributed lens 20 of the camera system 16 is functionally a patterned structure, i.e., the lens operates, or in some embodiments is also configured, as a patterned structure (because its active segments 32 are arranged in a spaced-apart relationship along the lens). Optical elements of the lens segments 32 are distributed/split into material pillars composing effectively the lens 20.

It should be understood that, similar to the pixel matrix pattern described above, the pattern of the inactive segments of the lens (and thus that of the active segments) may have fixed pattern parameter(s) or one or more varying pattern parameters or may be a random pattern in terms of pattern pitch, feature sizes and shape.

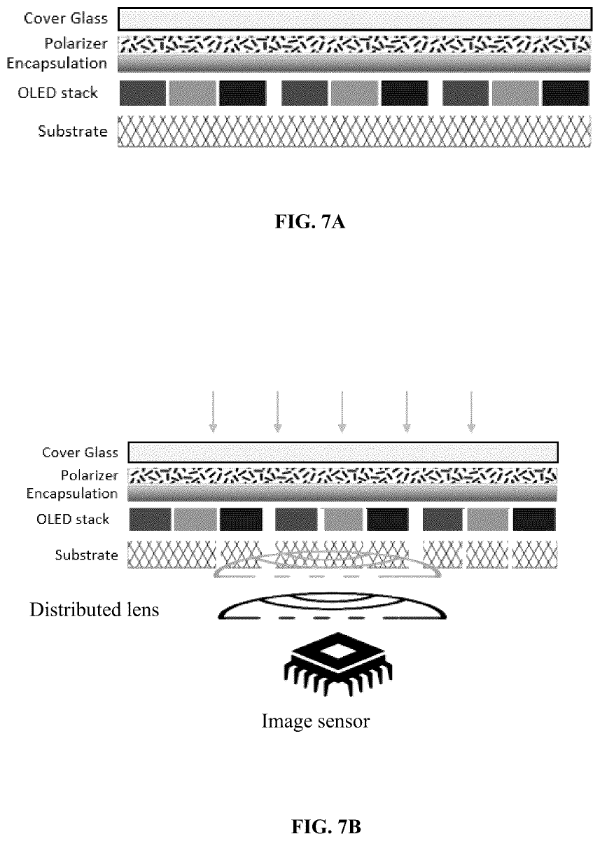

In some embodiments, as described above, the optical sensor unit may include a continuous flat light sensitive surface formed by a matrix of spaced-apart sensor pixels. In some other embodiments, the sensor pixels may be arranged in clusters. In this connection, reference is made to FIGS. 6A-6D, schematically illustrating an example of the display pixel matrix 14 and a relative accommodation of the pixel matrix 14 of the display unit and the sensor matrix 34 of the optical sensor unit.

FIG. 6A exemplifies a single display pixel P of the display pixel matrix. This pixel P is typically formed by a spaced-apart arrangement/pattern of subpixels SP—four such subpixels of primary colors R, G, G, B being shown in this non-limiting example—defining the inter-subpixel gaps S″. Gaps S′ and/or S″ may have a fixed spatial frequency throughout the region in the display, or may have a combination of fixed spatial frequency with randomness introduced to the entire or part of the region in the display.

FIG. 6B shows an arrangement of a few pixels, generally at P, of the display pixel matrix with inter-pixel gaps S′. The display pixel matrix has a pitch of a size a (e.g., a=55 μm). It should be understood, and also noted above, that the technique of the present disclosure is not limited to any parameter of the pixel matrix or subpixel arrangement. As already noted above, gaps S″ exist also between subpixels of the same display pixel and the subpixels of the neighboring display pixels P. Each one of the inter-pixel/inter-subpixel gaps can be utilized as a sensor pixel cluster P′, forming the sensor matrix 34 of the optical sensor unit according to the technique of the present disclosure.

FIG. 6C exemplifies a sensor pixel cluster P′ being a sub-array or sub-matrix of the sensor matrix 34 of the optical sensor unit. In this non-limiting example, the sensor pixel cluster P′ is a 4×4 matrix of 16 subpixels 44 (sensor elements) defining together a 10 μm diameter area, each subpixel 44 having a size of 2.5×2.5 μm.

The sensor pixel clusters P′ are aligned with the inter-subpixel spaces/gaps S″ and inter-pixel gaps S′ between them as shown in FIG. 6B. Pixel clusters denoted P′(S′) are those located in regions of the sensor matrix aligned with the inter-pixel gaps S′, and pixel clusters denoted P′(S″) are those located in the sensor matrix’ regions aligned within the inter-subpixel spaces S″. In the figure, a center-to-center distance between the locally adjacent pixel clusters P′ (camera/sensor pixels) is denoted b.

In a specific example of the sensor pixel matrix configuration with the pitch a=55 μm, the distance b between the sensor pixels P′ (clusters) is 27.5 μm. FIG. 6D shows the sensor matrix 34 of the optical sensor unit with the distributed sensor clusters/pixels P′, with a diameter of 10 μm each and distance of 27.5 μm between each two sensor clusters.

The maximal number of subpixels 44 in the sensor cluster P′ is selected such that the size of the cluster (being the sensor clusters of the same or neighboring pixels P) can fit the lateral size b of the inter-pixel gap S′ (space between the adjacent pixels P′) of the display unit 14. The active segments 32 of the distributed lens 20 are located above the sensor clusters P′.

Keeping in mind that the sensor pixel cluster P′ is a pixel matrix by itself, the above configuration provides high spatial resolution of image fragments (image data pieces) detectable by the optical sensor unit from the light field collected by the distributed lens 20.

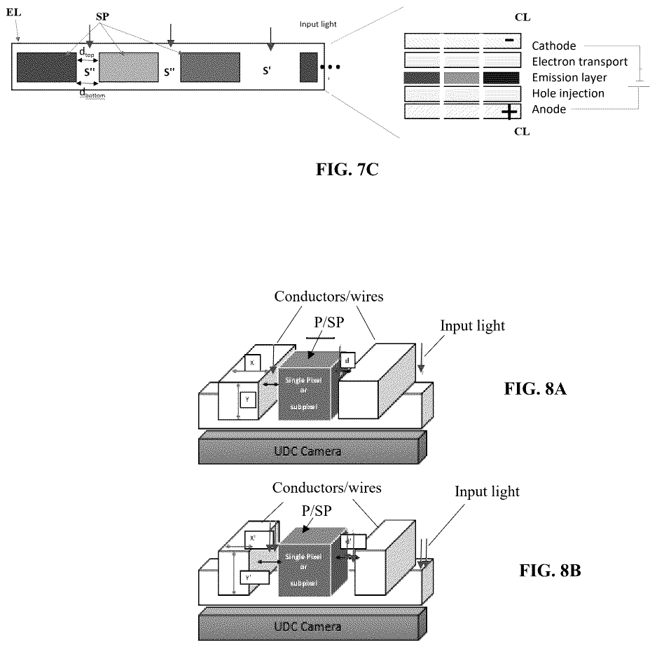

Reference is made to FIGS. 7A to 7C and FIGS. 8A-8C illustrating the aspect of the present disclosure for optimizing the display unit configuration for use with the under-display camera. As described above, in some embodiments the pixel matrix 14 of the display unit is configured with subpixel arrangement of light emitting elements. The light emitting elements may be of any known suitable type, e.g., may include any known suitable LED-based architecture, for example any one of the following types: OLED, POLED, AMOLED, TOLED, MicroLED.

FIG. 7A schematically exemplifies, in a self-explanatory manner, the conventional OLED display layers' structure. As shown, the OLED stack is placed on a substrate and is covered by a stack of encapsulation, polarizer and cover glass layers. In such structure, the substrate layer may not be optically transparent and may be a continuous layer.

FIG. 7B schematically illustrates how the distribution lens and image sensor of the under-display camera system of the present disclosure can be installed/mounted under or within the OLED display layer structure. To this end, the substrate layer may be made optically transparent and/or may be properly patterned (as schematically shown in the figure) in accordance with the pattern of the subpixels of the entire pixel matrix.

FIG. 7C illustrates schematically the configuration of the OLED stack within a display pixel P which in the present example is formed by three spaced-apart subpixels SP including a light emitting element of a typical LED-based architecture where the shape of the LEDs is of a rectangle flat cube, with a distance dₜₒₚ between the top surfaces of the adjacent LEDs being substantially equal to a distance d_{bottom} between the bottom surface of said adjacent LEDs. The emission layer EL (arrangement of LEDs is typically enclosed between electron and hole transport layers which interface, respectively, with cathode and anode conductor layers CL where the conductor/wire arrangement defines the footprint area of the pixel and/or subpixel.

In order to allow for more light to reach the distributed lens of camera system located under the OLED display layers structure, the inventors have optimized various elements of the LED layers (stack) structure. More specifically, several parameters of the LED stack structure need to be optimized to increase the amount of light passing through the pixel display spaces, while maintaining high-quality operation of the display unit, i.e. emission of the LEDs.

The LED stack configuration define such parameters as the area of the light emitting surface EL and the conductor/wire configuration (defined mainly by the LED conductor footprint) to provide current supply and thus provide desired light emission from a given light emission area. These structural parameters, while associated with the LED operation, directly affect the resulting dimensions/areas of the inter-pixel gaps S′ and inter-subpixel gaps S″ of the final display pixel matrix and thus the transparent areas affecting the amount of light that can reach the under-display camera.

FIGS. 8A to 8E exemplify various options for the LED structure optimization and arrangement of LEDs optimization.

FIGS. 8A and 8B exemplify the optimization by modifying configuration of conductors/wires, i.e., the conducting traces connected to each pixel or subpixel to deliver power (electricity) and/or control signals. In this configuration the geometry of the trace is modified to increase the height thereof while proportionally decreasing the width/depth of the conductor. By this, the same conductor cross section area is maintained, while creating a bigger distance between any two traces to enable more light to go through. More specifically, the figures exemplify how the cross-section area of the OLED conductors/wires in the x and y directions (also referred to as scan lines (x-direction), and data lines (y-direction) can be changed thus increasing the space (gap) between adjacent pixels and sub-pixels. In FIG. 8A, the conductors at opposite sides of the pixel/subpixel have dimensions x (width of cross section) and y (length of the cross section) defining aspect ratio x/y and a gap size d. As shown in FIG. 8B the geometry of the conductors is optimized towards dimensions x′<x and y′>y and a corresponding aspect ratio x′/y′<x/y resulting in a gap size d′>d. This change of the aspect ratio is achieved by configuring the conductors/wires with a smaller aspect ratio while keeping the value of conductor cross section area constant, thereby maintaining given/desired electrical properties (e.g., current density) of the LED operation while increasing the distance between two adjacent LEDs and according increasing the amount of input light reaching the under-display camera.

Another optimization technique is exemplified in FIGS. 8C-8E. FIGS. 8D and 8E show two examples of the optimized geometry of light emitting element, as compared to the conventional cubic-like geometry shown in FIG. 8C. The optimized geometry provides increased distance between two light emitting elements (subpixels) while keeping the same surface area of the light emitting surface of the light emitting element.

More specifically, the light emitting portion LE of the LED, being a volumetric structure, is changed from the standard cubic-like structure (i.e., structure having a rectangular cross-section as shown in FIG. 8C) to a volumetric dome-like structure (three-dimensional curved shape) shown in FIG. 8D, while keeping the surface area at least the same as of the standard flat cubic shape. By this, top surface area (emitting light) of the dome-like LED structure is increased as compared to the flat top surface of the cube and the bottom surface area is decreased resulting in that bottom distance, d′_{bottom} between the dome-shaped pixels/subpixels is larger than d_{bottom} between the cubic pixels/subpixels. Thus, for the LEDs of the given surface area (defined to provide desired emission from the LEDs), the gap between adjacent pixels and/or subpixels is increased. The increased gap area enables more light to go through the display unit and reach the under-display camera.

In addition, the bottom distance between the bottom surfaces of the adjacent LEDs can be increased by utilizing the technical solution of FIG. 8B.

FIG. 8E shows yet further example of an optimized configuration of the LED where the top light emitting portion of the LED is configured with increased surface area by making a curved/patterned top surface with an array of spaced-apart protrusions (rather than planar/flat). Such configuration allows to reduce the area of the base of the pixel/subpixel increasing the gap between two adjacent pixels. This enables more light to go through the display unit to the under-display camera.

The bottom distance d_{bottom} between the bottom surfaces of the adjacent LEDs can be further increased by utilizing the technical solution of FIG. 8B, and

[symbol]

The following are some examples of further embodiments of the present disclosure aimed at optimizing the configuration and operation of the display pixels to maximize the light passage through the display matrix to the under-display camera.

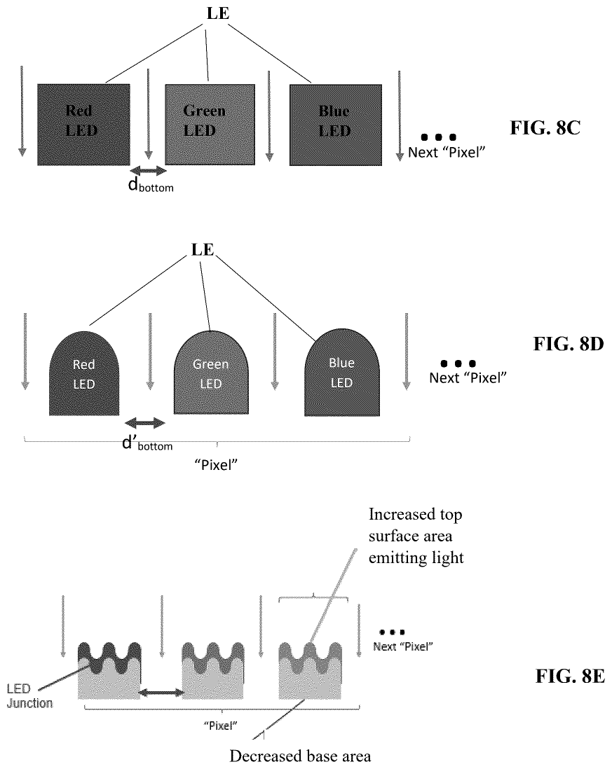

FIGS. 9A and 9B exemplify how the pixel matrix layer of the display unit can be optimized to increase amount of light reaching the under-display camera, based on the use of a layer of light blocking material placed on the back (i.e. non-light emitting surface) side of a subpixel (FIG. 9A) and use of combination of optimized pixel (LED) geometry and the layer of light blocking material at the bottom of the subpixel to serve as a light guide allowing light to go around the pixel.

The figures show two examples of a part of the display pixel matrix 14 where a display layer 1 (made of e.g., glass, PET, polycarbonate, ITO or any other standard material used to construct a backplane or substrate) carries the display pixels/subpixels (LEDs) on one side thereof and on its opposite side has a matrix of light absorbing regions (light absorbers) aligned with the LED carrying regions (light absorbers/blockers are right under the LEDS. These light absorbers are provided to reduce the diffraction occurring around the edges of the transparent regions (inter-pixel and inter-subpixel gaps) in between the LEDs. The light absorbers also block the light that might pass through the LEDs layers when the LEDs are in the OFF state. The light absorbers may be implemented by lithography or any other known in the art methods and materials.

In the example of FIG. 9B, increase of the light collection capability of the distributed lens of the under-display camera is achieved by providing the structure of the display pixel element (subpixel SP in case the pixel structure includes by array of subpixels) with a light directing assembly. As exemplified in FIG. 9B, the light directing assembly is formed by a pair of prisms PR₁ and PR₂.

It should be noted that all three elements of prism PR₁ can be a single element for simplicity of implementation; and similarly all three elements of prism PR₂ can be a single element; thus providing top element and bottom element between the LEDs.

The prisms PR₁ and PR₂ of the pair are configured symmetrically identically and at least partially surround (overhang/cover) the pixel element structure at opposite sides thereof. More specifically, as shown in the figure, one prism PR₁ of the pair surrounds the LED and the other prism PR₂ surrounds opposite side of the display layer below the LED, e.g., surrounds the light absorber. This configuration provides that input light hitting the prism PR₁ on top of the LED that would otherwise be lost, is “bypassing” the reflecting surface of LED and is directed by the prism PR₂ towards the under-display camera. Thus, light collection efficiency is improved. It should be noted, although not specifically shown, that, alternatively, the light directing assembly may include a curved fiber placed over the LEDs to provide the light bypassing by directing the input light, that would otherwise be reflected back, to reach the under-display camera.

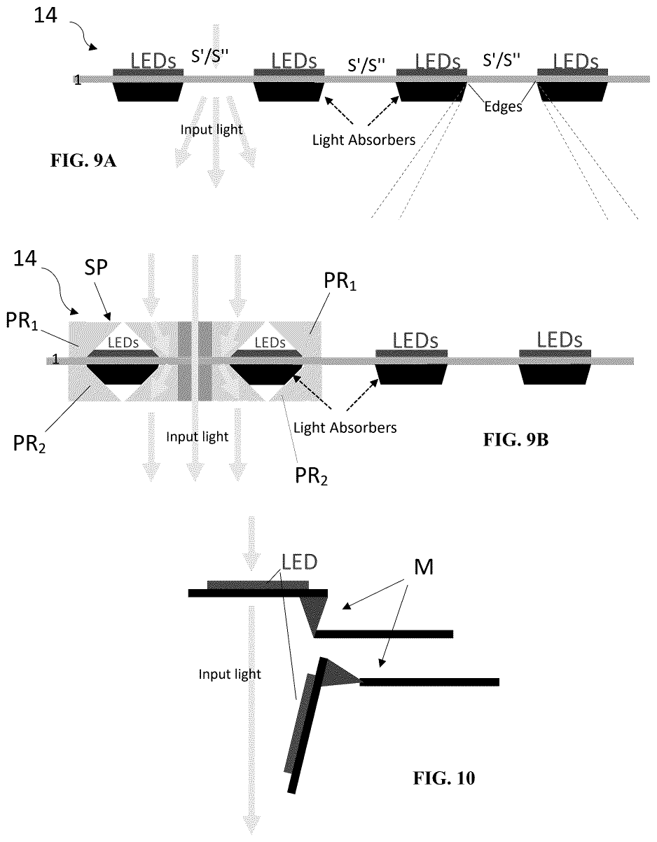

Reference is made to FIG. 10 exemplifying yet another possible configuration of a display unit of an electronic device enabling integration of an under-display camera system in the electronic device. According to this technique, each of at least some of the light emitting elements of the pixel matrix is associated with a movement mechanism configured to controllably shift the light emitting element between its operative position, in which a light emitting surface of the light emitting element extends along the display pixel matrix layer and is exposed to the input light, and its inoperative folded position forming a window for the input light to pass therethrough. As shown in the figure, the display pixel element structure (pixel or subpixel), exemplified here as LED, of the sub-pixel of the display pixel matrix is associated/equipped with a movement mechanism M (e.g. LED is placed on a micro-electromechanical system (MEMS)). This movement mechanism (e.g., MEMS) is configured to controllably shift the LED between its operative position, when the LED extends along the display pixel matrix layer and is thus exposed to the input light, and its inoperative folded position thereby opening a pixel size or subpixel-size window for the input light to pass through to the under-display camera. This figure depicts a configuration where each pixel or pixel group is placed on an electro-mechanical mechanism. The terms “operative position” and “inoperative position” of the LED refers to the operation of the display. As such, in the operative position, the “shutter” is closed and the emitting surface of the pixels are pointing in the direction of the user (“up”). At this position there are no spaces between pixels and light cannot go through to the under-display camera positioned under/below the display plane. In its inoperative position, each mechanism is positioned such that it has a minimal cross section in relation to the under-display camera. The result is that light is unobstructed to reach the under-display camera placed under that area of the display.

As described above and exemplified in the figures, with the use of the under-display camera with distributed lens 20, the image data generated by the sensor pixel matrix 34 of the optical sensor unit 24 is in the form of image fragments corresponding to the segments of the input light field incident on the upper panel 12 of the device and transmitted via spaces S defined by the display pixel matrix of the display unit 14. The image processor 26 of the camera system is configured and operable to merge all the image fragments and generate properly sharpened final/reconstructed image. As mentioned above and will be described more specifically further below, the image processing technique may be model-based and may utilize a dedicated deep NN trained to reconstruct from the image fragments a clear and sharp image of the object/scene.

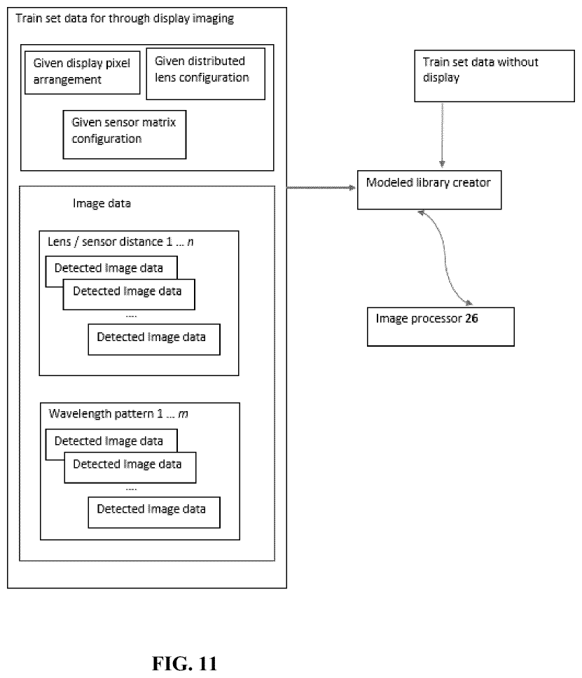

Reference is made to FIG. 11 illustrating schematically the process of modeled library creation and use of the library data by the image processor 26 of the given camera system installed in a given electronic device, i.e., behind the given pixel arrangement of the display unit. As shown in the figure in the self-explanatory manner, the modeled library creation includes model training stage using train set data (image data) obtained by a given lens-and-sensor setup with the lens (wavefront profile) operating as a distributed lens, i.e. located under the given display pixel matrix, and being directly exposed to incoming light with no display pi9xel matrix above it. Then the model is optimized using various data sets corresponding to different wavelengths, as well as different zoom parameters, to create a set of models to be used to reconstruct the image data from fragmented image pieces obtained via the distributed lens under various imaging conditions in the given display-camera set up.

1. An electronic device comprising:
a display screen unit comprising a display pixel matrix in a layer of a device panel exposed to an upper surface of the display screen unit; and
at least one under-display camera system comprising an imaging lens unit comprising a lens exposed to at least a part of the upper surface of the display screen unit via at least inter-pixel gaps of spaces defined by the display pixel matrix in at least a part of said display pixel matrix, said lens being configured as a distributed lens having a surface configured in accordance with a continuous light wavefront curvature of a lensing effect to be applied to light incident on said distributed lens entering the imaging lens unit via at least said inter-pixel gaps, such that spaced-apart lensing segments of the distributed lens defining respective spaced-apart surface portions of the continuous wavefront curvature are aligned with said at least inter-pixel gaps in said at least part of said display pixel matrix and are therefore directly exposed to the upper surface of the display screen unit via said at least inter-pixel gaps, while surface portions of the continuous wavefront curvature between said spaced-apart segments are screened from the upper surface by regions of the display pixel matrix outside said spaces defined by the display pixel matrix.

2. The device according to claim 1, wherein the at least one under-display camera system further comprises an optical sensor responsive to image fragments created by the imaging lens unit from light collected by said distributed lens to generate corresponding fragmented image data; and an image processor configured to receive and process said fragmented image data to reconstruct an image from the fragmented image data.

3. The device according to claim 1, wherein the spaces defined by the display pixel matrix further comprises inter-subpixel gaps, said spaced-apart segments of the distributed lens define respective spaced-apart surface portions of the continuous wavefront curvature aligned with said inter-subpixel gaps.

4. The device according to claim 1, wherein said lensing segments of the distributed lens correspond, respectively, to the portions of the continuous wavefront curvature, and are thus different from one another in at least one of geometry and orientation.

5. The device according to claim 1, wherein said distributed lens is entirely located below said layer of the device panel containing said pixel matrix.

6. The device according to claim 5, characterized by at least one of the following:
said surface of the distributed lens configured in accordance with the continuous wavefront curvature of the lensing effect is a continuous surface; and
the distributed lens is made of any one of the following material compositions: plastic, glass, polymer, polycarbonate, transparent conductor.

7. (canceled)

8. The device according to claim 4, wherein said surface of the distributed lens configured in accordance with the continuous wavefront curvature of the lensing effect is a patterned surface, said lensing segments being at least partially located in the spaces defined by the display pixel matrix of said at least part of the pixel matrix of the display layer.

9. The device according to claim 8, characterized by at least one of the following:
said lensing segments are at least partially located in the inter-pixel gaps and inter-subpixel gaps defined by the display pixel matrix in said at least part of the pixel matrix of the display layer,
at least some of said lensing segments are entirely located in the spaces defined by the pixel matrix in said at least part of the pixel matrix of the display layer;
said lensing segments are made of molding pillars made of material of refractive index greater than air and are configured with heights varying as a function of their position along the distributed lens;
said lensing segments are made of any one of the following material compositions: polymer, polycarbonate, glass, transparent semiconductor.

10. (canceled)

11. (canceled)

12. (canceled)

13. The device according to claim 1, wherein the display pixel matrix comprises a matrix of light emitting elements.

14. The device according to claim 13, wherein the light emitting element comprises a LED-based structure of any one of the following: OLED, POLED, AMOLED, TOLED.

15. The device according to claim 1, wherein said display pixel matrix comprises spaced-apart pixels, each pixel element comprising an arrangement of subpixels.

16. The device according to claim 15, wherein said arrangement of subpixels comprises a respective arrangement of light emitting elements.

17. The device according to claim 13, wherein the light emitting element is configured with a top portion having a three-dimensional shape configured to maximize a distance between two neighboring light emitting elements while keeping given operational parameters of the light emitting elements.

18. The device according to claim 17, characterized by one of the following:
said three-dimensional shape defines a dome-like structure; or
said three-dimensional shape defines a wave-like shape formed by a plurality of spaced-apart protrusions.

19. (canceled)

20. The device according to claim 13, characterized by at least one of the following:
conductors associated with the light emitting elements are configured with predetermined aspect ratio between length and width of a cross section of the conductor while keeping a given cross section area of the conductor, thereby maintaining electrical properties of the conductors and providing an increased distance between edges of two adjacent conductors associated with two adjacent light emitting elements, respectively;
the layer of the display pixel matrix comprises, on one side thereof, said matrix of the light emitting elements, and comprises, in an opposite side of said layer, a matrix of light absorbers, where the light absorbers are aligned with the light emitting elements, respectively, thereby reducing diffraction occurring around edges of the spaces in between the light emitting elements; and
the layer of the display pixel matrix comprises light directing elements associated with the light emitting elements, respectively, configured to increase amount of light, incident onto the display pixel matrix, passing through the spaces defined by the pixel matrix.

21. (canceled)

22. The device according to claim 13, wherein the layer of the display pixel matrix comprises light directing elements associated with the light emitting elements, respectively, configured to increase amount of light, incident onto the display pixel matrix, passing through the spaces defined by the pixel matrix, the device being characterized by one of the following: said light directing element comprises a pair of prisms at opposite sides of the light emitting element, or said light directing element comprises a curved fiber placed over the light emitting element.

23. (canceled)

24. (canceled)

25. The device according to claim 13, wherein each of at least some of the light emitting elements of the pixel matrix is associated with a movement mechanism configured to controllably shift the light emitting element between its operative position, in which a light emitting surface of the light emitting element extends along the display pixel matrix layer and is exposed to the input light, and its inoperative folded position forming a window for the input light to pass through to the distributed lens of the camera system.

26. The device according to claim 25, wherein said movement mechanism is an electro-mechanical mechanism.

27. The device according to claim 2, wherein the optical sensor unit and the distributed lens are spaced from one another by a medium of a material composition and a thickness selected to maintain image formation scheme of light collected by the lens segments of the distributed lens on a light sensitive structure of the optical sensor unit.

28. The device according to claim 27, wherein said material composition of the media comprises one of the following: polymer, polycarbonate, glass, transparent semiconductor.

29. The device according to claim 1, wherein said surface of the distributed lens configured in accordance with the continuous wavefront curvature of the lensing effect is a front surface of the distributed lens facing the upper surface of the display screen unit.

30. The device according to claim 1, wherein said surface of the distributed lens configured in accordance with the continuous wavefront curvature of the lensing effect is a rear surface of the imaging lens facing said sensor unit.

31. The device according to claim 2, wherein the optical sensor unit comprises a sensor matrix, sensors of said sensor matrix being aligned with the spaces defined by the display pixel matrix.

32. The device according to claim 2, wherein said optical sensor unit comprises a sensor matrix configured as a distributed cluster of sensor pixels, each cluster being a sub-matrix of said sensor matrix and the clusters being aligned with the spaces defined by the display pixel matrix of the display screen unit.

33. The device according to claim 2, wherein said image processor is configured and operable to process the data indicative of output of the optical sensor unit by applying to said data a model-based processing utilizing a machine learning model to generate image data in which diffraction and chromatic effects associated with light propagation through the distributed lens are compensated.

34. The device according to claim 1, wherein the camera system comprises at least one additional imaging lens unit comprising at least one respective additional lens configured as the distributed lens having a surface configured in accordance with a continuous light wavefront curvature of a lensing effect to be applied to light incident thereon via at least the inter-pixel gaps in at least one additional part of said display pixel matrix.

35. The device according to claim 1, comprising at least one additional camera system, at least two camera systems comprising the distributed lenses extending along, respectively, at least two spaced-apart regions corresponding to respective at least two parts of the pixel matrix of the display screen unit.

36. The device according to claim 34, wherein the camera system comprises an optical sensor being responsive to image fragments created by each of at least two imaging lens units.

37. The device according to claim 35, comprising a data processor configured and operable to communicate with an image processor of each of said at least two camera systems.

38. A camera system configured to be installed as a built-in module in an electronic device underneath a pixel matrix of a display screen unit of the electronic device, said camera module comprising:
an imaging lens unit comprising a lens having at least one of its front or rear surfaces configured in accordance a continuous wavefront curvature of a desired lensing effect, such that when the camera module is installed in the electronic device, said at least one surface of lens is exposed to input light entering the device via a transparent panel thereof and propagating through spaces defined by said pixel matrix of the device, said lens being thereby operable as a distributed lens formed by an array of spaced-apart active lensing segments aligned with the spaces defined by the pixel matrix of the display unit;
an optical sensor unit located underneath the imaging lens unit and being responsive to image fragments created by the imaging lens unit to generate fragmented image data corresponding to the lensing segments; and
an image processor configured and operable to process the fragmented image data and reconstruct a real image.

39. (canceled)

40. (canceled)

41. (canceled)

42. (canceled)

43. (canceled)

44. (canceled)

45. (canceled)

46. (canceled)

47. (canceled)
